(19) United States
(12) Patent Application Publication
(10) Pub. No.: US 2024/0322682 A1
(43) Pub. Date: Sep. 26, 2024

(54) VOLTAGE CONTROL CIRCUIT AND METHOD OF STARTING VOLTAGE CONTROL CIRCUIT

(71) Applicant: LAPIS Technology Co., Ltd., Yokohama (JP)

(72) Inventor: Yoichi FUEKI, Yokohama (JP)

(73) Assignee: LAPIS Technology Co., Ltd., Yokohama (JP)

(21) Appl. No.: 18/605,850

(22) Filed: Mar. 15, 2024

(30) Foreign Application Priority Data
Mar. 23, 2023 (JP) 2023-047297

(51) Int. Cl. H02M 3/155; H03K 19/0175

(52) U.S. Cl. CPC H02M 3/155; H03K 19/017509

(57) ABSTRACT

A voltage control circuit includes a shunt regulator, an output power source line connected to the shunt regulator, a switch connected between a first power source line and an output power source line, and a control circuit, in which the control circuit includes a first current source connected between the first power source line and the output power source line, a generation circuit having an input receiving a signal related to a potential of the first power source line and an output, and configured to generate a control signal at the output from the signal received at the input, a switch control circuit that generates a switch control signal, and an enable generation circuit that generates an enable signal for controlling the shunt regulator in response to a signal from the output of the second level shift circuit.

### CROSS-REFERENCE TO RELATED APPLICATION

This application claims priority under 35 USC 119 from Japanese Patent application No. 2023-047297 filed on Mar. 23, 2023, the disclosure of which is incorporated by reference herein.

### BACKGROUND

### Technical Field

The disclosure relates to a voltage control circuit and a method of starting the voltage control circuit.

### Description of Related Art

Patent Document 1 (International Publication No. 2006-063589) discloses a signal extraction circuit. The signal extraction circuit achieves both the acquisition of a stable power supply voltage and the extraction of an information signal from a high frequency signal that is modulated by an information signal and of which an amplitude changes dynamically. Specifically, a shunt regulator performs control such that a voltage obtained by rectifying a high frequency signal output from an antenna part with a rectifier circuit is stabilized at a predetermined voltage value. A signal extraction part extracts the information signal superimposed on the high frequency signal from a bypass current that is caused to flow by the shunt regulator for the above control when the voltage varies.

Devices such as RFID tags are used that operate by receiving power from an antenna by using a short-range wireless communication technology. Such a device receives power from an antenna and then converts the power to a required voltage level. There is a need for an integrated circuit that performs all operations of receiving power from an antenna.

However, there is a need for a structure to prevent a voltage exceeding an allowable withstand voltage from being applied to an integrated circuit when excessive power is received.

The disclosure provides a voltage control circuit that can perform power supply control such that power does not exceed a withstand voltage of an integrated circuit and a starting method for the voltage control circuit.

### SUMMARY

According to a first aspect of the disclosure, there is provided a voltage control circuit including a first power source line connected to an output of a power supply device; a shunt regulator having a reference voltage input; an output power source line connected to the shunt regulator; a switch connected between the first power source line and the output power source line; and a control circuit connected to the first power source line and the output power source line, in which the control circuit includes a generation circuit having an input receiving a signal related to a potential of the first power source line and an output, and configured to generate a control signal at the output from the signal received at the input, a first current source connected between the first power source line and the output power source line, a switch control circuit configured to generate a switch control signal for controlling the switch in response to the control signal from the output of the generation circuit, and connected between the first power source line and a second power source line different from the first power source line, and an enable generation circuit configured to generate an enable signal for controlling the shunt regulator in response to the control signal from the output of the generation circuit.

According to a second aspect of the disclosure, there is provided a method of starting a voltage control circuit, the method including supplying power from a power supply device to a first power source line, the first power source line being disconnected from an output power source line different from the first power source line by a switch; after the supply of power, generating a signal having a voltage between the first power source line and a second power source line different from the first power source line by using a signal generation circuit connected between the first power source line and the second power source line; changing a potential of the output power source line by using a first current source connected between the output power source line and the first power source line; generating a first signal from the signal by using a first level shift circuit connected between the first power source line and the second power source line, the first signal being applied to a transfer circuit connected between the output power source line and the second power source line from the first level shift circuit and being level-shifted to a signal having a level to which the transfer circuit is capable of responding; inputting the first signal into the transfer circuit and generating a second signal generated when the first signal propagates through the transfer circuit at an output of the transfer circuit; level-shifting the second signal by using a second level shift circuit connected between the first power source line and the second power source line to generate a third signal; causing a shunt regulator connected to the output power source line to operate in response to the third signal, and controlling a voltage of the output power source line by using the shunt regulator; and closing the switch in response to the third signal to connect the first power source line and the output power source line to each other after the shunt regulator starts operating.

### BRIEF DESCRIPTION OF THE DRAWINGS

FIG. 1 is a diagram schematically showing a configuration of a power receiving device according to the present embodiment.

FIG. 2 is a diagram schematically showing a configuration of main parts of a voltage control circuit according to the present embodiment.

FIG. 3 is a drawing showing exemplary waveforms at main nodes in the circuit shown in FIG. 2.

FIG. 4 is a diagram schematically showing a configuration of main parts of a voltage control circuit according to the present embodiment.

FIG. 5 is a drawing schematically showing a configuration of main part of a switch control circuit of the voltage control circuit according to the present embodiment.

FIG. 6 is a drawing schematically showing a configuration of main parts of an enable generation circuit and an output reset circuit of the voltage control circuit according to the present embodiment.

FIG. 7 is a drawing showing exemplary waveforms at main nodes in the circuits shown in FIGS. 4, 5, and 6.

FIG. 8 is a drawing showing the main steps in a method of starting the voltage control circuit according to the present embodiment.

### DESCRIPTION OF THE EMBODIMENTS

According to the above aspects, it is possible to provide a voltage control circuit that can perform power supply control such that power does not exceed a withstand voltage of an integrated circuit and a starting method for the voltage control circuit.

Hereinafter, each embodiment for carrying out the disclosure will be described with reference to the drawings.

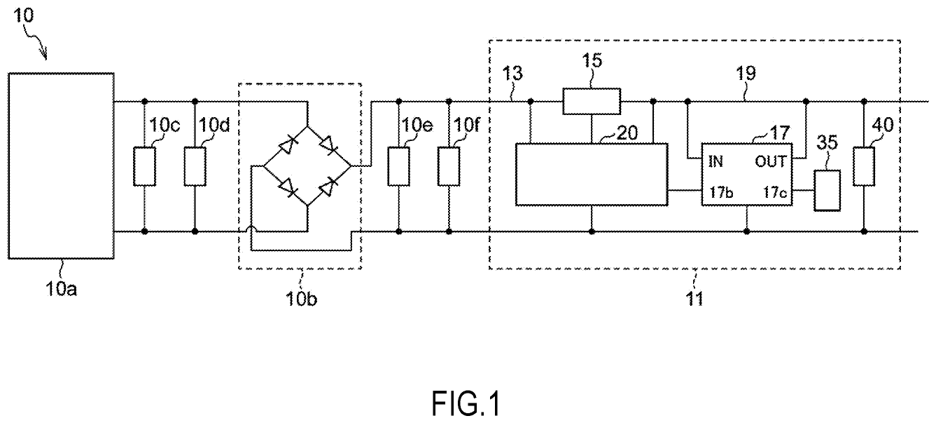

FIG. 1 is a drawing schematically showing a configuration of a power receiving device according to the present embodiment.

A power receiving device 10 may include a power supply device such as an antenna device 10a and a rectifier circuit 10b, an inductor 10c, a capacitor 10d, a limiter circuit 10e, a capacitor 10f, and a voltage control circuit 11. The power supply device is not limited to a combination of the antenna device 10a and the rectifier circuit 10b. The antenna device 10a is configured to receive high frequency power, and the high frequency power may be modulated to represent transmission information. The antenna device 10a is connected to a transmission device in the power receiving device 10 and can transmit a high frequency signal. The rectifier circuit 10b may include a connection of a rectifier element such as a diode bridge.

The inductor 10c and the capacitor 10d are connected in parallel and connected to an output of the antenna device 10a. An input of the rectifier circuit 10b receives power from the antenna device 10a via the inductor 10c and the capacitor 10d. The limiter circuit 10e and the capacitor 10f are connected to an output of rectifier circuit 10b. The output of the rectifier circuit 10b may be connected to the voltage control circuit 11 via the limiter circuit 10e and the capacitor 10f.

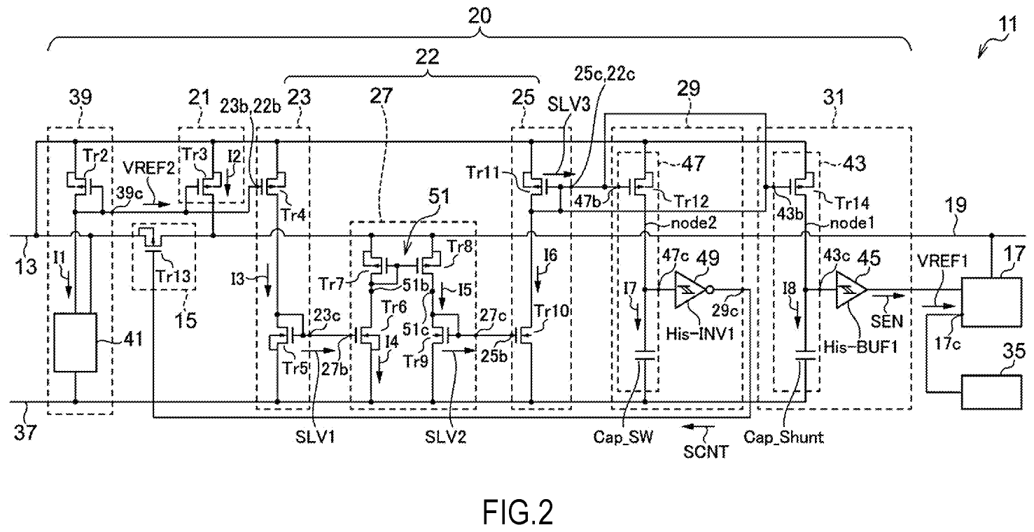

The voltage control circuit 11 includes a first power source line 13, a switch 15, a shunt regulator 17, an output power source line 19, and a control circuit 20. The first power source line 13 is connected to the output of the rectifier circuit 10b. The output power source line 19 is connected to an input IN and an output OUT of the shunt regulator 17. The shunt regulator 17 also has a control input 17b that receives an enable signal SEN (refer to FIG. 2). The shunt regulator 17 has a reference voltage input 17c connected to a first reference voltage source 35 and receiving a reference voltage VREF1 (refer to FIG. 2). The switch 15 is connected between the first power source line 13 and the output power source line 19.

The voltage control circuit 11 may further include a capacitor 40 (FIG. 1) connected to the output of the shunt regulator 17. The capacitor 40 stabilizes the output of the shunt regulator 17.

The control circuit 20 is connected to the first power source line 13 and the output power source line 19. The control circuit 20 controls opening and closing of the switch 15. The control circuit 20 controls starting of an operation of the shunt regulator 17.

FIG. 2 is a drawing schematically showing a configuration of main parts of the voltage control circuit according to the present embodiment. FIG. 2 depicts circuit symbols of p-type and n-type MOS transistors. A back gate of the n-type MOS transistor is connected to a second power source line 37 (for example, a VSS line). A back gate of the p-type MOS transistor is connected to a first power source line 13 (for example, an HVDD line) or an output power source line 19 (for example, an LVDD line). Specifically, the back gate of a p-type MOS transistor is connected to a power source line having a potential equal to or higher than a voltage applied to a source and a drain of the transistor.

Specifically, the control circuit 20 includes a first current source 21, a generation circuit 22, a switch control circuit 29, and an enable generation circuit 31. The generation circuit 22 has an input 22b that receives a signal related to a potential of the first power source line 13, and an output 22c. The generation circuit 22 generates a control signal (for example, SLV3) at the output 22c from a signal (for example, VREF2) received at the input 22b. The signal (for example, VREF2) applied to the input 22b of the generation circuit 22 can be generated in response to starting of the first power source line 13. The control signal (for example, SLV3) from the generation circuit 22 is provided to the switch control circuit 29 and the enable generation circuit 31. The switch control circuit 29 generates a switch control signal SCNT for controlling the switch 15. The enable generation circuit 31 generates an enable signal SEN for controlling the shunt regulator 17.

The exemplary generation circuit 22 includes a first level shift circuit 23, a second level shift circuit 25, and a transfer circuit 27. In the generation circuit 22, a signal propagates to the first level shift circuit 23, the transfer circuit 27, and the second level shift circuit 25 in this order. The first level shift circuit 23 and the second level shift circuit 25 operate between the first power source line 13 and the second power source line 37, while the transfer circuit 27 operates between the output power source line 19 and the second power source line 37. Therefore, the first level shift circuit 23 level-shifts a signal related to the potential of the first power source line 13 (for example, VREF2) to generate a level shift signal (for example, SLV1) at a level applicable to the transfer circuit 27. The second level shift circuit 25 level-shifts a signal (for example, SLV2) related to the potential of the output power source line 19 to generate a signal (for example, SLV3) at a level applicable to the subsequent circuits (the switch control circuit 29 and the enable generation circuit 31).

Next, the control circuit 20 will be described.

The first current source 21 is connected between the first power source line 13 and the output power source line 19. Specifically, the first level shift circuit 23 is connected between the first power source line 13 and the second power source line 37 and level-shifts, for example, a reference voltage VREF2 of a second reference voltage source 39 that is also connected between the first power source line 13 and the second power source line 37. The transfer circuit 27 has an input 27b and an output 27c, and transfers a signal received at the input 27b to the output 27c. The transfer circuit 27 is connected between the output power source line 19 and the second power source line 37. The second level shift circuit 25 is connected between the first power source line 13 and the second power source line 37, and level-shifts a voltage at the output 27c of the transfer circuit 27.

The switch control circuit 29 operates while connected between the first power source line 13 and the second power source line 37. The switch control circuit 29 generates a switch control signal SCNT for controlling the switch 15 in response to a signal from the output 25c of the second level shift circuit 25.

The enable generation circuit 31 operates while connected to the output 25c of the second level shift circuit 25. The enable generation circuit 31 generates the enable signal SEN for controlling an operation of the shunt regulator 17.

According to the voltage control circuit 11, power is supplied from the rectifier circuit 10b to the first power source line 13. During the supply of power, the switch control circuit 29 operates such that the switch 15 disconnects the output power source line 19 from the first power source line 13. In response to the supply of power, the first reference voltage source 35 and the second reference voltage source 39 connected between the first power source line 13 and the second power source line 37 become operable, and the first level shift circuit 23 level-shifts a signal from the second reference voltage source 39.

The first current source 21 causes a current to flow between the first power source line 13 and the output power source line 19 to change a potential of the output power source line 19. The transfer circuit 27 becomes operable in response to a change in the potential of the output power source line 19, and becomes capable of transmitting the signal from the first level shift circuit 23 to the second level shift circuit 25.

The enable generation circuit 31 is configured to generate the enable signal SEN in response to a signal from the second level shift circuit 25, and the enable signal SEN enables to operate the shunt regulator 17. In response to the enable signal SEN, the shunt regulator 17 becomes operable and controls the potential of the output power source line 19. The switch control circuit 29 is configured to generate a switch control signal SCNT in response to a signal from the output 25c of the second level shift circuit 25. The switch 15 is closed in response to the switch control signal SCNT, and the first power source line 13 is connected to the output power source line 19 via the switch 15. The first power source line 13 is connected to the shunt regulator 17 via the switch 15.

In the control circuit 20, the first reference voltage source 35 may be connected between the first power source line 13 and the second power source line 37. The first reference voltage source 35 provides the first reference voltage VREF1 to the reference voltage input 17c of the shunt regulator 17. The second reference voltage source 39 may be connected between the first power source line 13 and the second power source line 37, and the exemplary first current source 21 generates a current in response to the reference voltage VREF2 of the second reference voltage source 39.

The first reference voltage source 35 and the second reference voltage source 39 are connected between the first power source line 13 and the second power source line 37, and become operable and generate respective reference voltages when a current from the rectifier circuit is generated in the first power source line 13.

The exemplary second reference voltage source 39 may include a current source circuit 41 and a load transistor Tr2. The current source circuit 41 and the load transistor Tr2 are connected between the first power source line 13 and the second power source line 37 and operate, and generate the reference voltage VREF2. A gate and a drain of the load transistor Tr2 are connected to the current source circuit 41, and the load transistor Tr2 allows a current I1 of the current source circuit 41 to flow, and generates the reference voltage VREF2 at the output 39c of the second reference voltage source 39.

The enable generation circuit 31 may include a first delay circuit 43 and a first determination circuit 45.

The first delay circuit 43 is connected between the first power source line 13 and the second power source line 37, and is connected to the output 25c of the second level shift circuit 25 to receive a signal from the output 25c. The first determination circuit 45 performs a determination for controlling the shunt regulator 17 in response to a signal of the output 43c of the first delay circuit 43.

According to the voltage control circuit 11, the first delay circuit 43 further adds a first delay to a propagation time of a signal passing through the first level shift circuit 23, the transfer circuit 27, and the second level shift circuit 25, and stabilizes potential changes in the output power source line. The first delay is generated by the first delay circuit 43.

The switch control circuit 29 may include a second delay circuit 47 and a second determination circuit 49. The second delay circuit 47 is connected between the first power source line 13 and the second power source line 37, and is also connected to the output 25c of the second level shift circuit 25 to receive a signal from the output 25c. The second determination circuit 49 performs a determination for controlling the switch 15 in response to a signal of the output 47c of the second delay circuit 47.

Since the switch control circuit 29 is connected between the first power source line 13 and the second power source line 37, a logic value high level signal has the voltage of the first power source line 13, and a logic value low level signal has the voltage of the second power source line 37.

The exemplary switch 15 includes a p-type transistor Tr13. The p-type transistor Tr13 is connected to the output 29c of the switch control circuit 29. A source and a back gate of the p-type transistor Tr13 are connected to the first power source line 13, a drain of the p-type transistor Tr13 is connected to the output power source line 19, and a gate of the p-type transistor Tr13 is connected to the output 29c of the switch control circuit 29.

According to the voltage control circuit 11, the second delay circuit 47 further adds a second delay to a propagation time of a signal passing through the first level shift circuit 23, the transfer circuit 27, and the second level shift circuit 25, and stabilizes a potential of the output power source line 19 using the shunt regulator 17. The second delay is generated by the second delay circuit 47.

The exemplary first current source 21 may cause a current to flow in response to the reference voltage VREF2 of the second reference voltage source 39. However, a reference voltage for generating a current of the first current source 21 is not limited to the reference voltage VREF2. According to the voltage control circuit 11, the first current source 21 causes the current I2 to flow when there is a potential difference between the first power source line 13 and the output power source line 19.

The exemplary first current source 21 includes a p-type MOS transistor Tr3, a source and a back gate of the p-type MOS transistor Tr3 are connected to the first power source line 13, and a drain of the p-type MOS transistor Tr3 is connected to the output power source line 19.

When the power receiving device 10 is started, there is a potential difference between the first power source line 13 and the output power source line 19. For example, when a voltage of the first power source line 13 is higher than a voltage of the output power source line 19, a current flows from the first power source line 13 to the output power source line 19. Since the switch 15 is opened, the potential of the output power source line 19 increases, and the potential difference between the first power source line 13 and the output power source line 19 becomes smaller.

The first level shift circuit 23 includes an input 23b and an output 23c. The first level shift circuit 23 includes a first current source transistor Tr4 as a second current source and a first load transistor Tr5. The first current source transistor Tr4 is connected between the first power source line 13 and the second power source line 37. A gate of the first current source transistor Tr4 receives, for example, the reference voltage REF2 of the second reference voltage source 39 that is a reference voltage source which becomes operable in response to starting of the first power source line 13. The second reference voltage source 39 becomes operable in response to starting of the first power source line 13. The first load transistor Tr5 has a gate and a drain connected to the drain of the first current source transistor Tr4. The first load transistor Tr5 receives a current I3 from the first current source transistor Tr4, and generates a signal SLV1 according to the current I3.

The input 23b of the first level shift circuit 23 is connected to the gate of the first current source transistor Tr4. The output 23c of the first level shift circuit 23 is connected to the gate and the drain of the first load transistor Tr5.

According to the voltage control circuit 11, the first level shift circuit 23 operates between the first power source line 13 and the second power source line 37, and generates the signal SLV1 level-shifted to be applicable to the transfer circuit 27 that operates between the output power source line 19 and the second power source line 37.

The transfer circuit 27 has the input 27b and the output 27c. The transfer circuit 27 is connected between the output power source line 19 and the second power source line 37 and operates at an operating speed according to a voltage of the output power source line 19. The transfer circuit 27 includes a third current source transistor Tr6, a current mirror circuit 51, and a third load transistor Tr9. The third load transistor Tr9 causes a mirror current I5 of a current I4 flowing through the third current source transistor Tr6 to flow. The third current source transistor Tr6 has a gate connected to the output 23c of the first level shift circuit 23. The third load transistor Tr9 has a gate and a drain connected to the output 27c of the transfer circuit 27, and generates a signal SLV2 from the signal SLV1 at the output 23c of the first level shift circuit 23.

The current mirror circuit 51 has an input 51b and an output 51c, the input 51b is connected to the drain of the third current source transistor Tr6, and the output 51c is connected to the gate and the drain of the third load transistor Tr9. Specifically, the current mirror circuit 51 includes a transistor Tr7 and a transistor Tr8, a gate and a drain of the transistor Tr7 are connected to the input 51b, and a drain of the transistor Tr8 is connected to the output 51c. A gate of the transistor Tr7 and a gate of the transistor Tr8 are connected to each other.

According to the voltage control circuit 11, the transfer circuit 27 uses the third current source transistor Tr6, the third load transistor Tr9, and the current mirror circuit 51 that operate between the output power source line 19 and the second power source line 37 to provide signal propagation according to a potential level of the output power source line 19.

The second level shift circuit 25 has an input 25b connected to the output 27c of the transfer circuit 27 and an output 25c, and is connected between the first power source line 13 and the second power source line 37 to operate. The second level shift circuit 25 may include a second current source transistor Tr10 as a third current source and a second load transistor Tr11. The second load transistor Tr11 has a gate and a drain connected to the second current source transistor Tr10. The second current source transistor Tr10 has a gate that receives a signal from the output 27c of the transfer circuit 27. The output 25c of the second level shift circuit 25 is connected to the gate and the drain of the second load transistor Tr11. The second load transistor Tr11 causes a current I6 that is caused to flow by the second current source transistor Tr10 to flow. Through this operation, a signal SLV3 (level shift signal) is generated at the output 25c.

In the voltage control circuit 11, the second level shift circuit 25 generates a level-shifted signal from a signal from the transfer circuit 27 that operates between the output power source line 19 and the second power source line 37. Through this level shift, the signal SLV3 has a level applicable to the switch control circuit 29 and the enable generation circuit 31 that operate between the first power source line 13 and the second power source line 37.

The enable generation circuit 31 will be described. In the exemplary enable generation circuit 31, the first delay circuit 43 may include a transistor Tr14 and a capacitor Cap_Shunt. A current I8 from the transistor Tr14 charges or discharges the capacitor Cap_Shunt to create a delay.

Specifically, the gate of the transistor Tr14 receives the signal SLV3 from the second level shift circuit 25 via the input 43b of the first delay circuit 43. The drain of the transistor Tr14 is connected to the output 43c of the first delay circuit 43 and one end of the capacitor Cap_Shunt, and the other end of the capacitor Cap_Shunt is connected to the second power source line 37. One end of the capacitor Cap_Shunt, that is, a node node1 changes slowly.

In the first delay circuit 43, the capacitor Cap_Shunt is charged by using a current of the transistor Tr14 associated with the signal SLV3 from the second level shift circuit 25, and the first delay circuit 43 provides an additional delay to the delay of the transfer circuit 27.

The first determination circuit 45 may include a first Schmitt trigger circuit His-BUF1, and the first Schmitt trigger circuit His-BUF1 may be connected, for example, between the first power source line 13 and the second power source line 37.

According to the voltage control circuit 11, the first Schmitt trigger circuit His-BUF1 is provided in the first determination circuit 45, and thus enables a stable operation in the circuit of the power receiving device 10 that operates in a harsh noise environment.

The switch control circuit 29 will be described. In the exemplary switch control circuit 29, the second delay circuit 47 may include a transistor Tr12 and a capacitor Cap_SW. A current from transistor Tr12 charges or discharges the capacitor Cap_SW to create a delay.

Specifically, a gate of the transistor Tr12 receives the signal SLV3 from the second level shift circuit 25 via the input 47b of the second delay circuit 47. A drain of the transistor Tr12 is connected to the output 47c of the second delay circuit 47 and one end of the capacitor Cap_SW, and the other end of the capacitor Cap_SW is connected to the second power source line 37. One end of the capacitor Cap_SW, that is, a node node2 changes slowly.

The second determination circuit 49 may include a first Schmitt trigger circuit His-INV1, and the first Schmitt trigger circuit His-INV1 may be connected, for example, between the first power source line 13 and the second power source line 37.

In the second delay circuit 47, the capacitor Cap_SW is charged by using a current I7 of the transistor Tr12 associated with the signal SLV3 from the second level shift circuit 25, and the second delay circuit 47 provides an additional delay to the delay of the transfer circuit 27.

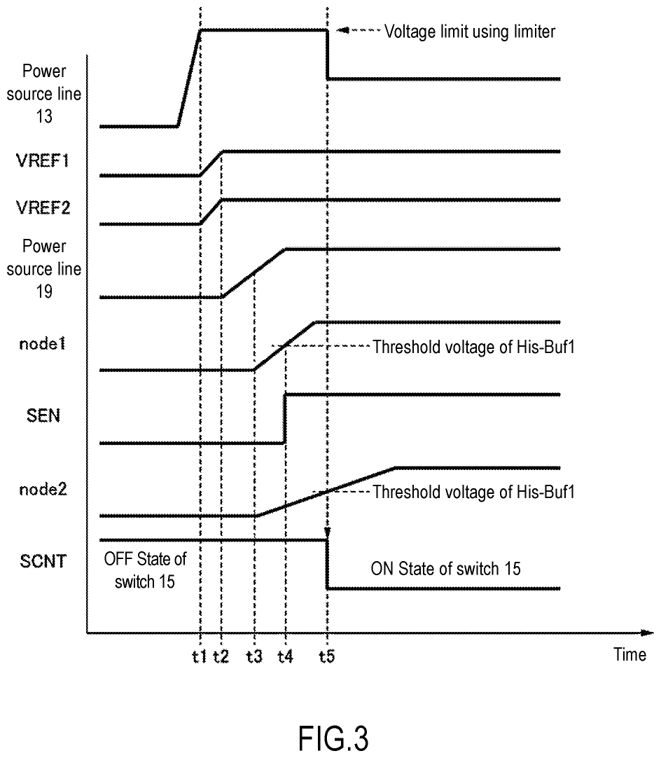

FIG. 3 is a drawing showing exemplary waveforms at main nodes in the circuit shown in FIG. 2. With reference to FIGS. 2 and 3, changes in each node when a power supply is started will be described.

Power at a resonant frequency of the inductor 10c and capacitor 10d shown in FIG. 1 is received by using the antenna device 10a. The received power is rectified by the rectifier circuit 10b and the capacitor 10d to be converted into a direct current. A voltage of the first power source line 13 when the power supply is started tends to increase, and reaches a limit voltage (HV voltage) at time t1, for example. The increase in voltage is limited by the limit voltage (HV voltage) of the limiter circuit 10e. The limitation of the voltage prevents a voltage value exceeding an allowable withstand voltage from being applied to a transistor used in a subsequent stage.

A BIAS generation circuit (the first reference voltage source 35 and the second reference voltage source 39) connected to the first power source line 13 is started. The first reference voltage source 35 and the second reference voltage source 39 generate the reference voltages VREF1 and VREF2 according to the first power source line 13. These reference voltages reach their respective steady-state values at time t2, for example. However, the steady-state values may not be reached at the same time. The reference voltage VREF1 is provided to the shunt regulator 17, and the reference voltage VREF2 is provided to the first current source 21 and the first level shift circuit 23.

Around time t2, the first current source 21 begins to provide the current I2 from the first power source line 13 to the output power source line 19, and the capacitor 40 is charged and the voltage of the output power source line 19 increases.

In response to the voltage increase at the output power source line 19, for example, around time t3, the first level shift circuit 23, the transfer circuit 27, and the second level shift circuit 25 become operable. Specifically, signal propagation from the first level shift circuit 23 to the second level shift circuit 25 via the transfer circuit 27 becomes possible. When the voltage of the output power source line 19 increases to such an extent that the voltage exceeds threshold voltages of the third load transistors Tr9 and Tr7 of the transfer circuit 27, a circuit operation becomes possible. At this time point, the voltage of the output power source line 19 has not reached a target voltage.

When the first level shift circuit 23, transfer circuit 27, and second level shift circuit 25 become operable, the delay circuits of the switch control circuit 29 and enable generation circuit 31 begin to operate and charge the respective capacitors in the delay circuits. However, at this time point, the voltage of the output power source line 19 has not reached the target voltage.

First, at time t4, the determination circuit 45 of the enable generation circuit 31 operates to generate the enable signal SEN. In response to this, the shunt regulator 17 operates. The shunt regulator 17 operates to control the voltage of the output power source line 19.

Next, at time t5, the determination circuit 49 of the switch control circuit 29 operates to generate the switch control signal SCNT. In response to this, the p-type transistor Tr13 of the switch 15 is turned on. The switch 15 connects the first power source line 13 to the output power source line 19. The shunt regulator 17 operates to control the voltages of the first power source line 13 and the output power source line 19. The voltage of the first power source line 13 decreases from the limiter voltage to a regulated voltage.

In order to realize the above starting sequence, the following operations occur in the chronological order. First stage: starting of the first power source line 13 and turning-off of the switch 15.

Second stage: starting of the shunt regulator 17.

Third stage: turning-on of the switch 15.

The estimation of a starting time of the first power source line 13 is defined by a capacitance of the capacitor 40, a desired voltage value of the output power source line 19, and a value of the current I2, and is provided by the following formula:

(capacitance of capacitor 40)×(desired voltage value of output power source line 19)/(current I2)

A starting time of the shunt regulator 17 is defined by a capacitance of the capacitor Cap_Shunt, a value of the current I8, and a threshold voltage of the Schmitt trigger circuit His-BUF1.

(capacitance of capacitor Cap_Shunt)×(threshold voltage of Schmitt trigger circuit His-BUF1)/(current I8)

The time until the switch 15 is turned on is defined by a capacitance of the capacitor Cap_SW, a value of the current I7, and a threshold voltage of the Schmitt trigger circuit His-INV1.

(capacitance of capacitor Cap_SW)×(threshold voltage of Schmitt trigger circuit His-INV1)/(current I7)

As described above, the switch 15 is provided between the first power source line 13 and the output power source line 19 to disconnect the first power source line 13 and the output power source line 19 from each other at the time of starting. The turning-on of the switch 15 is controlled by using the control circuit 20 that operates in response to starting of the first power source line 13 and the output power source line 19. In response to the starting of the first power source line 13 and the output power source line 19, the shunt regulator 17 operates. After the shunt regulator 17 operates, the first power source line 13 and the output power source line 19 are connected to each other. According to this power supply starting sequence, the power supply can be reliably started without exceeding a withstand voltage of the transistors in the circuit, and a desired voltage can be obtained by controlling the shunt regulator 17.

Finally, since the first power source line 13 and the output power source line 19 are connected to each other, the shunt regulator 17 controls the voltage of the output of the rectifier circuit. No additional regulator circuit is required.

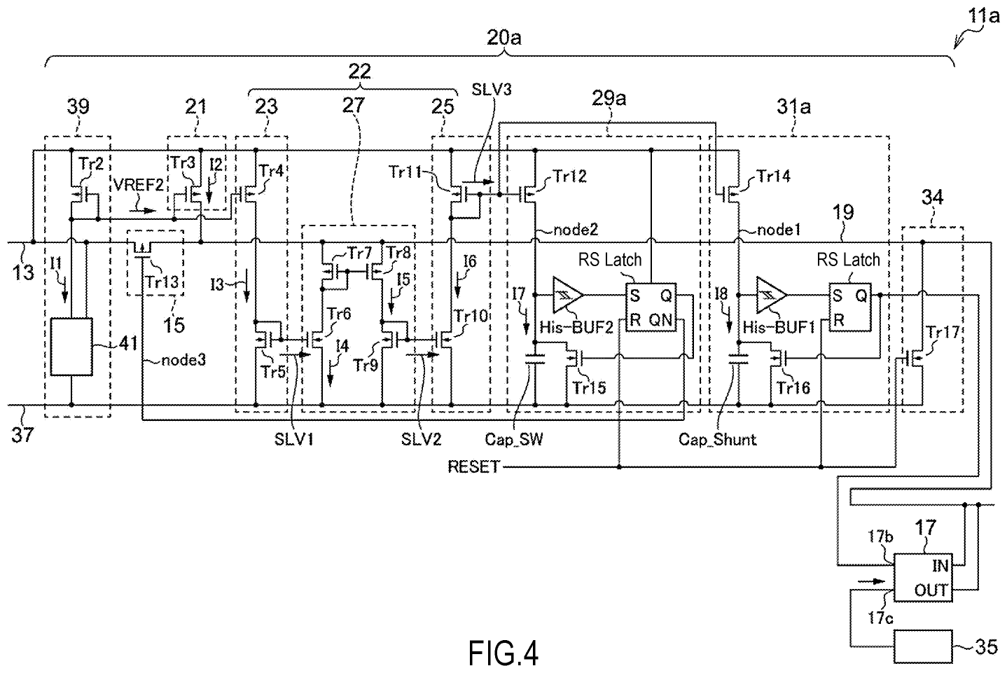

FIG. 4 is a drawing schematically showing a configuration of main parts of a voltage control circuit according to the present embodiment.

A voltage control circuit 11a includes a first power source line 13, a switch 15, a shunt regulator 17, an output power source line 19, and a control circuit 20a. Specifically, the control circuit 20a includes a first current source 21, a first level shift circuit 23, a second level shift circuit 25, a transfer circuit 27, a switch control circuit 29a, an enable generation circuit 31a, and an output reset circuit 34.

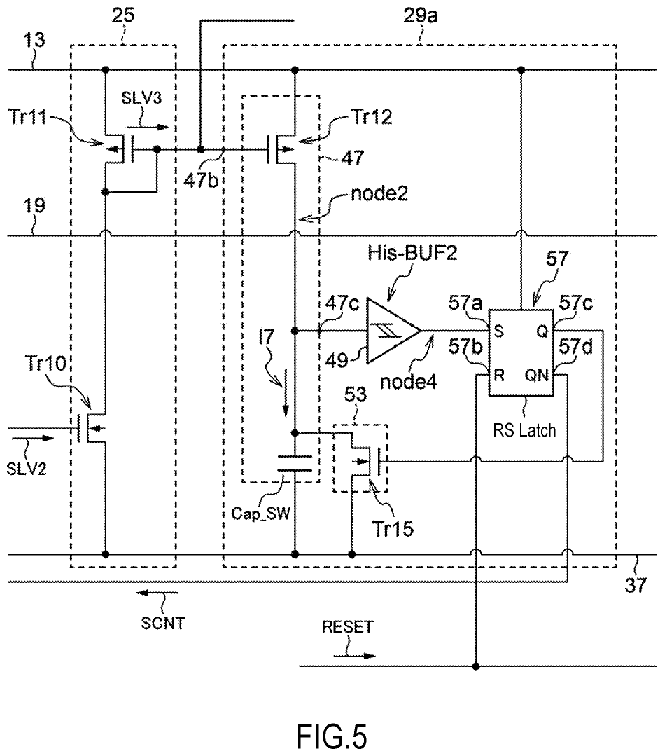

FIG. 5 is a drawing schematically showing a configuration of main parts of the switch control circuit of the voltage control circuit according to the present embodiment.

The switch control circuit 29a will be described. In the exemplary switch control circuit 29a, similar to the switch control circuit 29, the second delay circuit 47 includes a transistor Tr12 and a capacitor Cap_SW, and the current I7 from the transistor Tr12 charges or discharges the capacitor Cap_SW to generate a delay. One end of the capacitor Cap_SW, that is, a node node2 changes slowly.

The second determination circuit 49 may include a first Schmitt trigger circuit His-BUF2, and the first Schmitt trigger circuit His-BUF2 may be connected, for example, between the first power source line 13 and the second power source line 37.

In the second delay circuit 47, the capacitor Cap_SW is charged by using the current I7 of the transistor Tr12 associated with the signal SLV3 from the second level shift circuit 25, and the second delay circuit 47 provides an additional delay to the delay of the transfer circuit 27.

The exemplary switch control circuit 29a further includes a reset circuit 53 and an RS latch circuit 57.

The RS latch circuit 57 has a set input 57a connected to the output of the second determination circuit 49 and a reset input 57b connected to the reset line RST. The RS latch circuit 57 provides values at Q output 57c and QN output 57d in response to inputs to the set input 57a and the reset input 57b. The QN output 57d of the RS latch circuit 57 generates the switch control signal SCNT. The Q output 57c of the RS latch circuit 57 controls a reset operation of the reset circuit 53. The reset circuit 53 is connected to the output 47c of the second delay circuit 47 and resets a delay operation of the second delay circuit 47.

Specifically, the reset circuit 53 includes a reset transistor Tr15, and a gate of the reset transistor Tr15 receives a Q signal from the output 57c of the RS latch circuit 57. A drain of the reset transistor Tr15 is connected to the drain of the transistor Tr12 and one end of the capacitor Cap_SW. When the reset transistor Tr15 is turned on, electric charge in the capacitor Cap_SW is released.

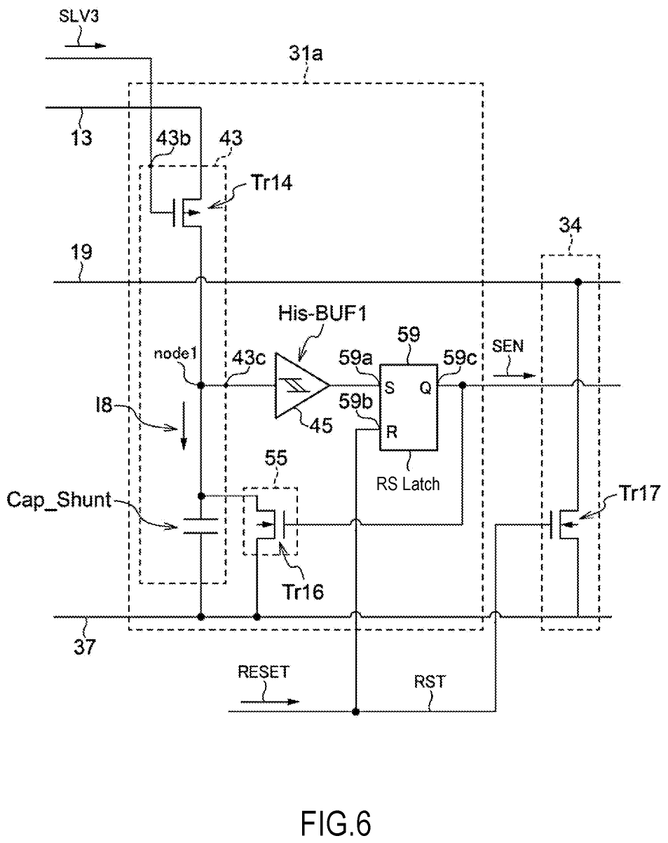

FIG. 6 is a diagram schematically showing a configuration of main parts of the enable generation circuit and the output reset circuit of the voltage control circuit according to the present embodiment.

The enable generation circuit 31a will be described. In the exemplary enable generation circuit 31a, similarly to the enable generation circuit 31, the first delay circuit 43 includes a transistor Tr14 and a capacitor Cap_Shunt, and a current from the transistor Tr14 charges or discharges the capacitor Cap_Shunt to generate a delay. One end of the capacitor Cap_Shunt, that is, the node node1 changes slowly.

The first determination circuit 45 may include a second Schmitt trigger circuit His-BUF1, and the second Schmitt trigger circuit His-BUF1 may be connected, for example, between the first power source line 13 and the second power source line 37.

In the first delay circuit 43, the capacitor Cap_Shunt is charged by using the current I8 of the transistor Tr14 associated with the signal SLV3 from the second level shift circuit 25, and the first delay circuit 43 provides an additional delay to the delay of the transfer circuit 27.

The exemplary enable generation circuit 31a further includes a reset circuit 55 and an RS latch circuit 59.

The RS latch circuit 59 has a set input 59a connected to the output of the first determination circuit 45 and a reset input 59b connected to the reset line RST. The RS latch circuit 59 provides a value to a Q output 59c in response to inputs to the set input 59a and the reset input 59b. The Q output 59c of the RS latch circuit 59 generates the enable signal SEN. The Q output 59c of the RS latch circuit 59 controls a reset operation of the reset circuit 55. The reset circuit 55 is connected to the output 43c of the first delay circuit 43 and resets a delay operation of the first delay circuit 43.

Specifically, the reset circuit 55 includes a reset transistor Tr16, and a gate of the reset transistor Tr16 receives a Q signal from the output 59c of the RS latch circuit 59. A drain of the reset transistor Tr16 is connected to the drain of the transistor Tr14 and one end of the capacitor Cap_Shunt. When the reset transistor Tr16 is turned on, electric charge in the capacitor Cap_Shunt is released.

The output reset circuit 34 resets the output power source line 19 in response to a reset signal RESET. The exemplary output reset circuit 34 includes a transistor Tr17, and a gate of the transistor Tr17 is connected to the reset line RST to receive the reset signal RESET. A drain of the transistor Tr17 is connected to the output power source line 19, and when the transistor Tr17 is turned on, the output power source line 19 is connected to a ground line.

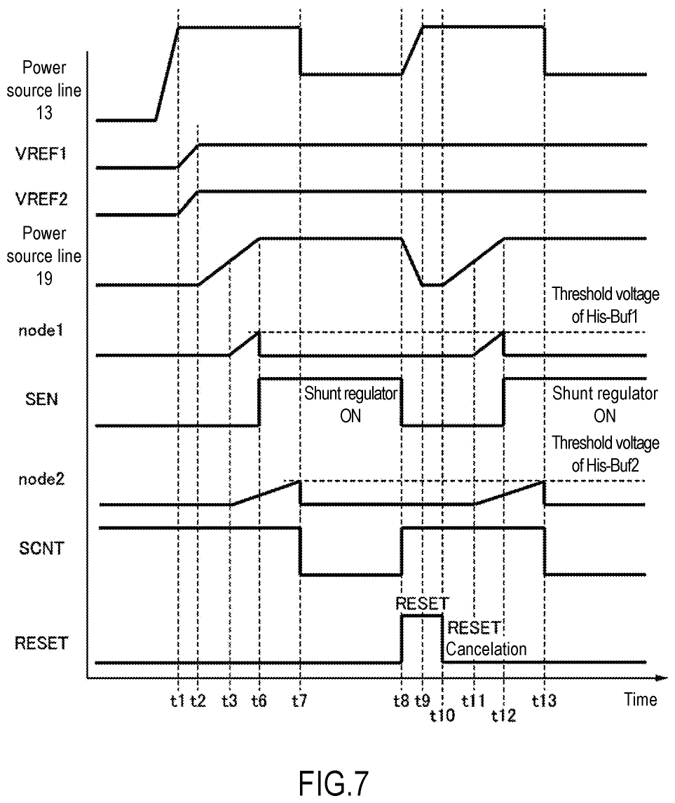

FIG. 7 is a drawing showing exemplary waveforms at main nodes in the circuits shown in FIGS. 4, 5, and 6. With reference to FIGS. 4, 5, 6, and 7, changes in each node when the power supply is started will be described.

An operation from time t1 to time t3 is the same as that related to the waveforms in FIG. 3. The description of power supply starting begins at time t6.

After time t6, a potential (node2) of the output power source line 19 increases. In response to the increase in the potential of the output power source line 19, a potential of the output (node1) of the first delay circuit 43 increases.

At time t6, when this potential exceeds a threshold value of the Schmitt trigger circuit His-BUF1, the output of the Schmitt trigger circuit His-BUF1 is inverted and the RS latch circuit 59 is set. In response to the setting of the RS latch circuit 59, the enable generation circuit 31a generates the enable signal SEN to start an operation of the shunt regulator 17. In response to the setting of the RS latch circuit 59, the output of the first delay circuit 43 is reset, and electric charge in the capacitor Cap_Shunt is released.

After time t3, an output of the second delay circuit 47 increases.

At time t7, when this potential exceeds the threshold value of the Schmitt trigger circuit His-BUF2, the RS latch circuit 57 is set in response to the change in the output of the Schmitt trigger circuit His-BUF2. In response to this setting, the RS latch circuit 57 generates a high level signal at the Q output 57c, and the reset circuit 53 resets the output of the second delay circuit 47. The transistor Tr15 is turned on, and electric charge in the capacitor Cap_SW is released.

The RS latch circuit 57 generates a low level signal at the QN output 57d. As a result, the switch control circuit 29a generates the switch control signal SCNT to turn on the switch 15. In response to the turning-on of the switch 15, the first power source line 13 is connected to the shunt regulator 17 via the output power source line 19.

Through such a sequence, normal starting is completed.

Next, operations related to the reset signal will be described.

At time t8, the reset signal RESET is applied to the reset line RST. The reset signal RESET is applied to the latch circuit 57 of the switch control circuit 29a, the latch circuit 59 of the enable generation circuit 31a, and the output reset circuit 34.

In response to the reset signal RESET, the latch circuit 57 of the switch control circuit 29a and the latch circuit 59 of the enable generation circuit 31a enter a reset state. The latch circuit 57 opens the switch 15 and disconnects the first power source line 13 from the output power source line 19. The latch circuit 59 stops the operation of the shunt regulator 17. The output reset circuit 34 connects the output power source line 19 to the second power source line 37 (ground line).

As a result, a potential of the first power source line 13 increases and a potential of the output power source line 19 decreases.

Around time t9, the first power source line 13 increases to a voltage defined by the limiter, and the output power source line 19 is grounded.

At time t10, the reset signal RESET is canceled. The output reset circuit 34 disconnects the output power source line 19 from the second power source line 37 (ground line). However, the switch 15 is in an open state. Again, the output power source line 19 is charged from the first power source line 13 via the first current source 21.

At time t11, when the potential of the output power source line 19 increases to a voltage level at which the transfer circuit 27 can operate, charging begins in the first delay circuit 43 and the second delay circuit 47.

At time t12, first, the Schmitt trigger circuit His-BUF1 of the enable generation circuit 31a inverts an output value in response to the voltage of the node node1 (charging node) of the first delay circuit 43, generates the enable signal SEN, and also resets the first delay circuit 43. In response to the enable signal SEN, the shunt regulator 17 operates to control the voltage of output power source line 19.

At time t13, the Schmitt trigger circuit His-BUF2 of the switch control circuit 29a is inverted in response to the voltage of the node node2 (charging node) of the second delay circuit 47, generates the switch control signal SCNT, and also resets the second delay circuit 47. In response to the switch control signal SCNT, the switch 15 is closed.

Through such a sequence, the normal starting of the operations associated with the reset signal is completed.

In the voltage control circuit 11 already described, circuits such as a hysteresis inverter (His-INV1) and a hysteresis buffer (His-BUF1) are used in the determination circuits (45, 49). However, a comparator may be used in the determination circuits (45, 49) to determine voltages of the outputs of the delay circuits (43, 47).

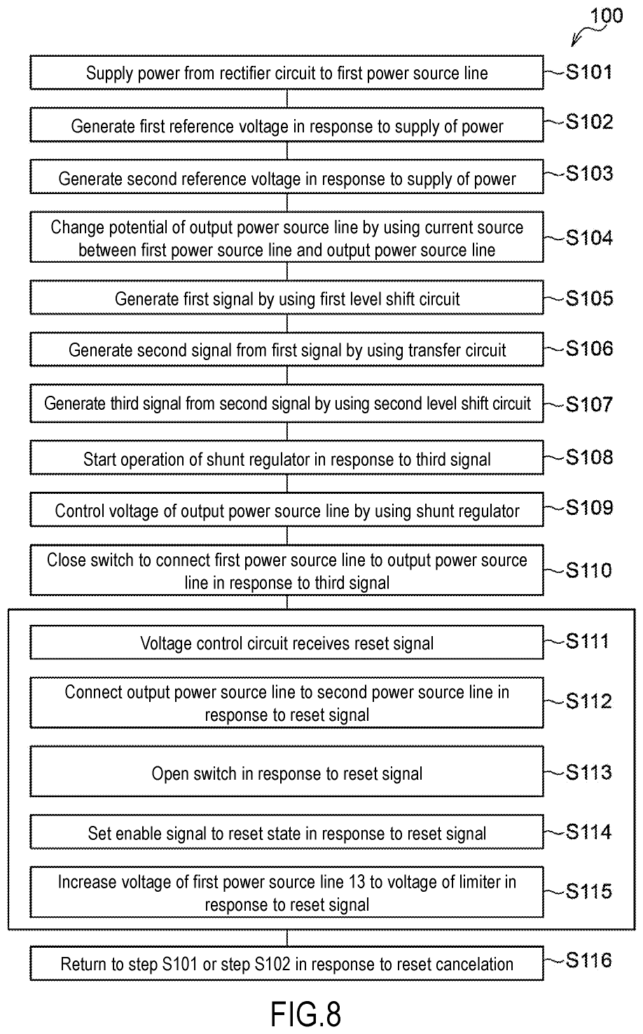

FIG. 8 is a drawing showing main steps in a method of starting the voltage control circuit according to this embodiment. In the following description, a method of starting the voltage control circuit 11 will be described with reference to the main steps.

A starting method 100 may include at least one step shown below.

In step S101, power is supplied from the rectifier circuit 10b to the first power source line 13. While the switch 15 is provided between the first power source line 13 and the output power source line 19, the switch 15 is opened when a voltage of the first power source line 13 increases due to the supply of power. The switch 15 separates the first power source line 13 from the output power source line 19. The shunt regulator 17 is not operating.

In step S102, the first reference voltage VREF1 is generated in response to the supply of power. The generated first reference voltage VREF1 may be provided to the shunt regulator 17. This provision is performed until the shunt regulator 17 operates in response to the enable signal SEN.

In step S103, in response to the supply of power, the second reference voltage generation circuit is used as a signal generation circuit to generate a signal having a voltage between the first power source line 13 and the second power source line 37, for example, the second reference voltage VREF2. For example, the second reference voltage VREF2 may be provided to the first current source 21 as a reference voltage. The second reference voltage VREF2 may be provided to the first level shift circuit 23, for example, as a signal (VREF2) related to a potential of the first power source line 13. The second reference voltage VREF2 may be generated before the first reference voltage VREF1 is generated, and the first reference voltage VREF1 and the second reference voltage VREF2 may be generated simultaneously.

In step S104, the potential of the output power source line 19 is changed by using the first current source 21 between the first power source line 13 and the output power source line 19. Specifically, the first current source 21 causes a current to flow into the output power source line 19. For example, the first current source 21 may receive the second reference voltage VREF2.

In step S105, a first signal (for example, SLV1) is generated by level-shifting the signal (for example, VREF2) received as a signal related to the potential of the first power source line 13 by using the first level shift circuit 23 connected between the first power source line 13 and the second power source line 37.

In step S106, the first signal (for example, SLV1) is input to the transfer circuit 27, and a second signal (for example, SLV2) generated by the first signal propagating through the transfer circuit is generated at the output of the transfer circuit 27. Specifically, the second signal (for example, SLV2) generated by the transfer circuit 27 that is configured such that the first signal (for example, SLV1) propagates is generated at the output 27c of the transfer circuit 27.

In step S107, the second signal (for example, SLV2) is received, and the second signal (for example, SLV2) is level-shifted by using the second level shift circuit 25 to generate a third signal (for example, SLV3).

In step S108, the enable signal SEN is generated in response to the third signal (for example, SLV3), and an operation of the shunt regulator 17 is started.

In step S109, a voltage of the output power source line 19 is controlled by using the shunt regulator 17. The shunt regulator 17 has already received the first reference voltage VREF1.

In step S110, a switch control signal SCNT is generated in response to the third signal (for example, SLV3), the switch 15 is closed such that the first power source line 13 and the output power source line 19 are connected to each other. The shunt regulator 17 already controls voltages of the first power source line 13 and the output power source line 19.

According to this starting method 100, stable starting of the shunt regulator can be achieved over a wide range of input power from the rectifier circuit.

The starting method 100 may further include the following steps.

In step S111, the voltage control circuit 11 may receive the reset signal RESET.

In step S112, in response to the reset signal RESET, the output power source line 19 is connected to the second power source line 37 to reset the output power source line 19.

In step S113, the switch 15 is opened in response to the reset signal RESET. Specifically, the switch control signal SCNT is reset in response to the reset signal RESET.

In step S114, the shunt regulator 17 is reset. Specifically, the enable signal SEN is reset in response to the reset signal RESET.

In step S115, the voltage of the first power source line 13 increases in response to the reset signal RESET.

In step S116, in response to the reset cancelation, the process returns to step S101 or step S102.

The voltage control circuit and the control method therefor according to the present embodiment are not limited to RFID tags that receive antenna power, and are applicable to circuit systems that provide a control voltage from power of a power source line of a high voltage system to a power source line of a low voltage system.

The background art of the voltage control circuit and the control method therefor according to the present embodiment will be described. There are, for example, the following two methods in a power supply of the background art.

In the first method, a supply line of a rectifier circuit is connected to a shunt regulator. The shunt regulator generates a power supply voltage of a high potential system. Another regulator is provided for an output of the shunt regulator. Another regulator generates a power supply voltage of a low potential system.

In the second method, a supply line of a rectifier circuit is connected to two shunt regulators. One shunt regulator generates a power supply voltage of a high potential system. The other shunt regulator generates a power supply voltage of a low potential system.

When the received power is large, the shunt regulator maintains the set voltage of the shunt regulator by causing an excess current to flow to the low-potential power source line. However, in a case where starting timing control for the shunt regulator is not appropriate, the shunt regulator outputs a voltage that does not reach the set voltage or exceeds the set voltage. Thus, it is difficult to control the shunt regulator.

The shunt regulator sets a power supply voltage thereof on the basis of a reference voltage value. As for the starting order, it is preferable to start a bias circuit that generates the reference voltage value first.

In order to ensure starting of the shunt regulator, a (delayed) enable signal is applied after providing the reference voltage to the shunt regulator. In this case, a voltage exceeding the set voltage may appear at the output of the shunt regulator due to a delay in the starting of the shunt regulator.

In the first method, when large power is received, an increase speed of the voltage of the high potential system tends to increase. In the second method, an increase speed of the voltage of the high potential system and the voltage of the low potential system increases. In either method, the shunt regulator may not be able to be controlled in time.

According to the above aspect, there is provided a voltage control circuit that enables reliable power control such that a withstand voltage of an integrated circuit is not exceeded, and a starting method for the voltage control circuit.

The present embodiment has various aspects.

A voltage control circuit according to a first aspect of the present embodiment includes a first power source line connected to an output of a power supply device; a shunt regulator having a reference voltage input; an output power source line connected to the shunt regulator; a switch connected between the first power source line and the output power source line; and a control circuit connected to the first power source line and the output power source line, in which the control circuit includes a generation circuit having an input receiving a signal related to a potential of the first power source line and an output, and configured to generate a control signal at the output from the signal received at the input, a first current source connected between the first power source line and the output power source line, a switch control circuit configured to generate a switch control signal for controlling the switch in response to the control signal from the output of the generation circuit, and connected between the first power source line and a second power source line different from the first power source line, and an enable generation circuit configured to generate an enable signal for controlling the shunt regulator in response to the control signal from the output of the generation circuit.

In the voltage control circuit of a second aspect according to the first aspect, the generation circuit may include a transfer circuit having an input and an output, configured to transfer a signal received at the input to the output, and connected between the output power source line and the second power source line, a first level shift circuit connected between the first power source line and the second power source line, and configured to level-shift a signal related to the potential of the first power source line to generate a signal applicable to the input of the transfer circuit at the output, and a second level shift circuit configured to level-shift a voltage of the output of the transfer circuit and connected between the first power source line and the second power source line, and the switch control circuit and the enable generation circuit may be connected to an output of the second level shift circuit.

In the voltage control circuit of a third aspect according to the first aspect or the second aspect, the enable generation circuit may include a first delay circuit connected between the first power source line and the second power source line and connected to the output of the generation circuit, and a first determination circuit that performs a determination for controlling the shunt regulator in response to a signal of an output of the first delay circuit.

In the voltage control circuit of a fourth aspect according to any one of the first aspect to the third aspect, the switch control circuit may include a second delay circuit connected between the first power source line and the second power source line and connected to the output of the generation circuit, and a second determination circuit that performs a determination for controlling the switch in response to a signal of an output of the second delay circuit.

The voltage control circuit of a fifth aspect according to the second aspect may include a first reference voltage source connected between the first power source line and the second power source line and connected to the reference voltage input of the shunt regulator; and a second reference voltage source connected between the first power source line and the second power source line and configured to generate a reference voltage, in which the first current source may cause a current to flow in response to the reference voltage of the second reference voltage source, and the first level shift circuit may receive the reference voltage of the second reference voltage source.

In the voltage control circuit of a sixth aspect of the second aspect, the first level shift circuit may include a first current source transistor receiving the signal related to the potential of the first power source line, and a first load transistor having a gate and a drain connected to the first current source transistor, and the output of the first level shift circuit may be connected to the gate and the drain of the first load transistor.

In the voltage control circuit of a seventh aspect according to the second aspect, the second level shift circuit may include a second current source transistor receiving a signal of the output of the transfer circuit, and a second load transistor having a gate and a drain connected to the second current source transistor, and the output of the second level shift circuit may be connected to the gate and the drain of the second load transistor.

In the voltage control circuit of an eighth aspect according to the second aspect, the transfer circuit may include a third current source transistor connected to the output of the first level shift circuit, a current mirror circuit having an input connected to the third current source transistor, and a third load transistor connected to an output of the current mirror circuit and causing a mirror current to flow, and the output of the transfer circuit may be connected to a gate and a drain of the third load transistor.

In the voltage control circuit of a ninth aspect according to the third aspect, the first determination circuit may include a first Schmitt trigger circuit connected between the first power source line and the second power source line, and a first latch circuit connected to an output of the first Schmitt trigger circuit and configured to receive a reset signal.

In the voltage control circuit of a tenth aspect according to the fourth aspect, the second determination circuit may include a second Schmitt trigger circuit connected between the first power source line and the second power source line, and a latch circuit connected to an output of the second Schmitt trigger circuit and configured to receive a reset signal.

A method of starting the voltage control circuit according to an eleventh aspect of the present embodiment includes supplying power from a power supply device to a first power source line, the first power source line being disconnected from an output power source line different from the first power source line by a switch; after the supply of power, generating a signal having a voltage between the first power source line and a second power source line different from the first power source line by using a signal generation circuit connected between the first power source line and the second power source line; changing a potential of the output power source line by using a first current source connected between the output power source line and the first power source line; generating a first signal from the signal by using a first level shift circuit connected between the first power source line and the second power source line, the first signal being applied to a transfer circuit connected between the output power source line and the second power source line from the first level shift circuit and being level-shifted to a signal having a level to which the transfer circuit is capable of responding; inputting the first signal into the transfer circuit and generating a second signal generated when the first signal propagates through the transfer circuit at an output of the transfer circuit; level-shifting the second signal by using a second level shift circuit connected between the first power source line and the second power source line to generate a third signal; causing a shunt regulator connected to the output power source line to operate in response to the third signal, and controlling a voltage of the output power source line by using the shunt regulator; and closing the switch in response to the third signal to connect the first power source line and the output power source line to each other after the shunt regulator starts operating.

The method of starting the voltage control circuit of a twelfth aspect according to the eleventh aspect may further include applying a reference voltage to the shunt regulator before the shunt regulator starts operating.

The disclosure is not limited to the embodiments described above, and can be implemented with various changes without departing from the concept of the disclosure. All of these are included in the technical idea of the disclosure.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A voltage control circuit comprising:
a first power source line connected to an output of a power supply device;
a shunt regulator having a reference voltage input;
an output power source line connected to the shunt regulator;
a switch connected between the first power source line and the output power source line; and
a control circuit connected to the first power source line and the output power source line, wherein
the control circuit includes
a generation circuit having an input receiving a signal related to a potential of the first power source line and an output, and configured to generate a control signal at the output from the signal received at the input,
a first current source connected between the first power source line and the output power source line,
a switch control circuit configured to generate a switch control signal for controlling the switch in response to the control signal from the output of the generation circuit, and connected between the first power source line and a second power source line different from the first power source line, and
an enable generation circuit configured to generate an enable signal for controlling the shunt regulator in response to the control signal from the output of the generation circuit.

2. The voltage control circuit according to claim 1, wherein
the generation circuit includes
a transfer circuit having an input and an output, configured to transfer a signal received at the input to the output, and connected between the output power source line and the second power source line,
a first level shift circuit connected between the first power source line and the second power source line, and configured to level-shift a signal related to the potential of the first power source line to generate a signal applicable to the input of the transfer circuit at the output, and
a second level shift circuit configured to level-shift a voltage of the output of the transfer circuit and connected between the first power source line and the second power source line,
wherein the switch control circuit and the enable generation circuit are connected to an output of the second level shift circuit.

3. The voltage control circuit according to claim 1, wherein
the enable generation circuit includes
a first delay circuit connected between the first power source line and the second power source line and connected to the output of the generation circuit, and
a first determination circuit that performs a determination for controlling the shunt regulator in response to a signal of an output of the first delay circuit.

4. The voltage control circuit according to claim 1, wherein
the switch control circuit includes
a second delay circuit connected between the first power source line and the second power source line and connected to the output of the generation circuit, and
a second determination circuit that performs a determination for controlling the switch in response to a signal of an output of the second delay circuit.

5. The voltage control circuit according to claim 2, further comprising:
a first reference voltage source connected between the first power source line and the second power source line and connected to the reference voltage input of the shunt regulator; and
a second reference voltage source connected between the first power source line and the second power source line and configured to generate a reference voltage, wherein
the first current source causes a current to flow in response to the reference voltage of the second reference voltage source, and
the first level shift circuit receives the reference voltage of the second reference voltage source.

6. The voltage control circuit according to claim 2, wherein
the first level shift circuit includes a first current source transistor receiving the signal related to the potential of the first power source line, and a first load transistor having a gate and a drain connected to the first current source transistor, and
the output of the first level shift circuit is connected to the gate and the drain of the first load transistor.

7. The voltage control circuit according to claim 2, wherein
the second level shift circuit includes a second current source transistor receiving a signal of the output of the transfer circuit, and a second load transistor having a gate and a drain connected to the second current source transistor, and
the output of the second level shift circuit is connected to the gate and the drain of the second load transistor.

8. The voltage control circuit according to claim 2, wherein
the transfer circuit includes a third current source transistor connected to the output of the first level shift circuit, a current mirror circuit having an input connected to the third current source transistor, and a third load transistor connected to an output of the current mirror circuit and causing a mirror current to flow, and
the output of the transfer circuit is connected to a gate and a drain of the third load transistor.

9. The voltage control circuit according to claim 3, wherein
the first determination circuit includes a first Schmitt trigger circuit connected between the first power source line and the second power source line, and a first latch circuit connected to an output of the first Schmitt trigger circuit and configured to receive a reset signal.

10. The voltage control circuit according to claim 4, wherein
the second determination circuit includes a second Schmitt trigger circuit connected between the first power source line and the second power source line, and a second latch circuit connected to an output of the second Schmitt trigger circuit and configured to receive a reset signal.

11. A method of starting a voltage control circuit, the method comprising:
supplying power from a power supply device to a first power source line, the first power source line being disconnected from an output power source line different from the first power source line by a switch;
after supplying the power, generating a signal having a voltage between the first power source line and a second power source line different from the first power source line by using a signal generation circuit connected between the first power source line and the second power source line;
changing a potential of the output power source line by using a first current source connected between the output power source line and the first power source line;
generating a first signal from the signal by using a first level shift circuit connected between the first power source line and the second power source line, the first signal being applied to a transfer circuit connected between the output power source line and the second power source line from the first level shift circuit and being level-shifted to a signal having a level to which the transfer circuit is capable of responding;
inputting the first signal into the transfer circuit and generating a second signal generated when the first signal propagates through the transfer circuit at an output of the transfer circuit;
level-shifting the second signal by using a second level shift circuit connected between the first power source line and the second power source line to generate a third signal;
causing a shunt regulator connected to the output power source line to operate in response to the third signal, and controlling a voltage of the output power source line by using the shunt regulator; and
closing the switch in response to the third signal to connect the first power source line and the output power source line to each other after the shunt regulator starts operating.

12. The method according to claim 11, further comprising:
applying a reference voltage to the shunt regulator before the shunt regulator starts operating.
